(19) United States
(12) Patent Application Publication
(10) Pub. No.: US 2015/0094973 A1
(43) Pub. Date: Apr. 2, 2015

(54) SYSTEM FOR MEASURING EXCITATION CHARACTERISTICS OF MAGNETIC ASSEMBLIES USING DIRECT CURRENT

(71) Applicant: Vanguard Instruments Company, Inc., Ontario, CA (US)

(72) Inventors: Oleh Iwanusiw, Toronto (CA); Iurii Glado, Ternopil (UA)

(21) Appl. No.: 14/044,688

(22) Filed: Oct. 2, 2013

(51) Int. Cl. G01R 33/12

(52) U.S. Cl. CPC G01R 33/12
USPC 702/65

(57) ABSTRACT

A device and method to measure the excitation characteristics of magnetic assemblies using reversible direct current and converting direct current excitation data to alternating current excitation data at any power frequency.

### FIELD OF THE INVENTION

The present invention relates to testing magnetic assemblies, such as transformers, and more specifically to a device and method to measure the excitation characteristics of magnetic assemblies using reversible direct current and a method for converting the direct current (DC) excitation data to alternating current (AC) excitation data at any power frequency.

### BACKGROUND

According to the ANSI/IEEE C57.13.1 Standard, entitled “Guide for Field Testing of Relaying Current Transformers”, incorporated herein by reference in its entirety, the following items need to be verified on current transformers 100 destined for relaying applications:

1. Ratio

2. Polarity

3. Insulation resistance

4. Winding resistance

5. Excitation characteristics.

The most difficult test of the five listed above is the “excitation test.” The excitation test requires the application of voltage and current (kVA) well above the typical operating conditions of the current transformer 100.

Currently available conventional test equipment that can be used for the ANSI/IEEE tests listed above would typically consist of line operated and adjustable voltage/current sources, analogue or digital voltmeters and ammeters and, in some cases, specialized testers. The conventional equipment can be used for generating voltage and current that would appear on the secondary windings 104 of instrument current transformers 100 under normal operating and fault conditions, and thereby are suitable for conducting the excitation test in a non-operational unit. To test most typical current transformer 100 installations, the voltage and current sources need to have a low impedance output of up to about 10 kVA. However, sources of this capacity are typically heavy and bulky. So currently used devices have smaller voltage and current sources with high source impedance and less than the desired kVA perform the tests. Another disadvantage of current testing devices is the lack of adequate power at a test site. The lack of adequate power prevents the devices from supplying adequate power to conduct the required tests accurately.

In addition to being bulky, heavy and difficult to operate, conventional test equipment does not properly control all the variables affecting current transformer performance. This results in an overall inaccurate performance.

Therefore there is a need for a device to measure the excitation characteristics of magnetic assemblies using reversible direct current and a method for converting the direct current excitation data to alternating current excitation data at any power frequency.

### BRIEF DESCRIPTION OF THE DRAWINGS

These and other features, aspects and advantages of the present invention will become better understood with regard to the following description, appended claims, and accompanying figures where:

FIG. 1 is a diagram of a prior art current transformer;

FIG. 2 is a graph of applied voltage and current plotted with respect to time;

FIG. 3 is a graph of integrated DC voltage, volt-seconds, and current, both plotted with respect to time;

FIG. 4 is a graph of (1) a high-power voltage at power frequencies applied to a winding of a magnetic assembly and a measurement of excitation current plotted on log-log graph paper and (2) a graph of a low level voltage range using reversible direct current whose measurements have been converted to power frequencies and plotted on log-log graph paper; and

FIG. 5 is a device useful to measure the excitation characteristics of a current transformer using reversible direct current.

### DETAILED DESCRIPTION

The present invention overcomes the limitations of the prior art by providing a device to measure the excitation characteristics of a current transformer using reversible direct current and a method for converting the direct current excitation data to alternating current excitation data at any power frequency. The present invention provides a device and a method for testing magnetic assemblies, especially current transformers eliminating the problems in the prior art and providing reliable tests of current transformer performance even with the testing device consuming considerably less power.

The testing of magnetic assemblies, such as transformers, especially current transformers, requires the application of appropriate power frequency excitation that simulates normal as well as fault operating conditions. These signal generators require considerable power to operate, are heavy and voluminous. To avoid the need for large power sources, such magnetic assemblies can be tested by direct current that is periodically reversed. Magnetic testing using DC produces results that are different from those using a typical power frequency test. The present invention provides both a device and a method that allows the magnetic assembly, such as, for example, a current transformer, to be conveniently tested using DC excitation and then converts the tests results obtained from DC tests to AC test results at the power frequency of the transformer being tested.

As will be understood by those with skill in the art with reference to this disclosure, a magnetic assembly like a current transformer 100 does not need the application of high voltage and high current in order for a device to test the performance of the current transformer 100 accurately. Magnetic theory can be used to determine the performance of not only current transformers 100, but all magnetic assemblies like power transformers, generators, motors, voltage transformers and reactors. It is the magnetic field, namely the peak magnetizing current and the integral of the applied voltage that determine the performance of the test sample. The peak magnetizing current cannot be reduced. However, the applied voltage can be substantially reduced, drastically reducing the power requirement of the test set up. As the integral of the applied voltage depends on the period, or frequency of the voltage, maximum advantage can be attained by reducing the test frequency to zero or, in other words, using DC excitation. This allows for a maximum reduction in test kVA and allows the test equipment to be smaller, portable and consume little power, and in fact the testing device can be powered from a typical service outlet.

All dimensions specified in this disclosure are by way of example only and are not intended to be limiting. Further, the proportions shown in these Figures are not necessarily to scale. As will be understood by those with skill in the art with reference to this disclosure, the actual dimensions and proportions of any system, any device or part of a system or device disclosed in this disclosure will be determined by its intended use.

Methods and devices that implement the embodiments of the various features of the invention will now be described with reference to the drawings. The drawings and the associated descriptions are provided to illustrate embodiments of the invention and not to limit the scope of the invention. Reference in the specification to “one embodiment” or “an embodiment” is intended to indicate that a particular feature, structure, or characteristic described in connection with the embodiment is included in at least an embodiment of the invention. The appearances of the phrase “in one embodiment” or “an embodiment” in various places in the specification are not necessarily all referring to the same embodiment.

Throughout the drawings, reference numbers are re-used to indicate correspondence between referenced elements. In addition, the first digit of each reference number indicates the figure where the element first appears.

As used in this disclosure, except where the context requires otherwise, the term “comprise” and variations of the term, such as “comprising”, “comprises” and “comprised” are not intended to exclude other additives, components, integers or steps.

In the following description, specific details are given to provide a thorough understanding of the embodiments. However, it will be understood by one of ordinary skill in the art that the embodiments may be practiced without these specific details. Well-known circuits, structures and techniques may not be shown in detail in order not to obscure the embodiments. For example, circuits may be shown in block diagrams in order not to obscure the embodiments in unnecessary detail.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be rearranged. A process is terminated when its operations are completed. A process may correspond to a method, a function, a procedure, a subroutine, a subprogram, etc. When a process corresponds to a function, its termination corresponds to a return of the function to the calling function or the main function.

Moreover, a storage may represent one or more devices for storing data, including read-only memory (ROM), random access memory (RAM), magnetic disk storage mediums, optical storage mediums, flash memory devices and/or other machine readable mediums for storing information. The term “machine readable medium” includes, but is not limited to portable or fixed storage devices, optical storage devices, wireless channels and various other mediums capable of storing, containing or carrying instruction(s) and/or data.

Furthermore, embodiments may be implemented by hardware, software, firmware, middleware, microcode, or a combination thereof. When implemented in software, firmware, middleware or microcode, the program code or code segments to perform the necessary tasks may be stored in a machine-readable medium such as a storage medium or other storage(s). One or more than one processor may perform the necessary tasks in series, distributed, concurrently or in parallel. A code segment may represent a procedure, a function, a subprogram, a program, a routine, a subroutine, a module, a software package, a class, or a combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted through a suitable means including memory sharing, message passing, token passing, network transmission, etc.

In the following description, certain terminology is used to describe certain features of one or more embodiments of the invention.

The term “current transformer” refers to a transformer that produces a current in its secondary circuit that is in proportion to its primary current.

The term “knee point” refers to one of three selectable methods: 1) the point at which a line tangent to the log-log plot has an angle of 45 degrees, 2) the point at which a line tangent to the log-log plot has an angle of 30 degrees, 3) the point at which the rms current will in crease by 50% if the average-reading ac voltage is increased by 10%. Each of these three methods is called out in either an ANSI/IEEE or an IEC standard.

Various embodiments provide a device to measure the excitation characteristics of a current transformer using reversible direct current and a method for converting the direct current excitation data to alternating current excitation data at any power frequency. One embodiment of the present invention provides a device to measure the excitation characteristics of a current transformer using reversible direct current. In another embodiment, there is provided a method for converting the direct current excitation data to alternating current excitation data at any power frequency. The device and method will now be disclosed in detail.

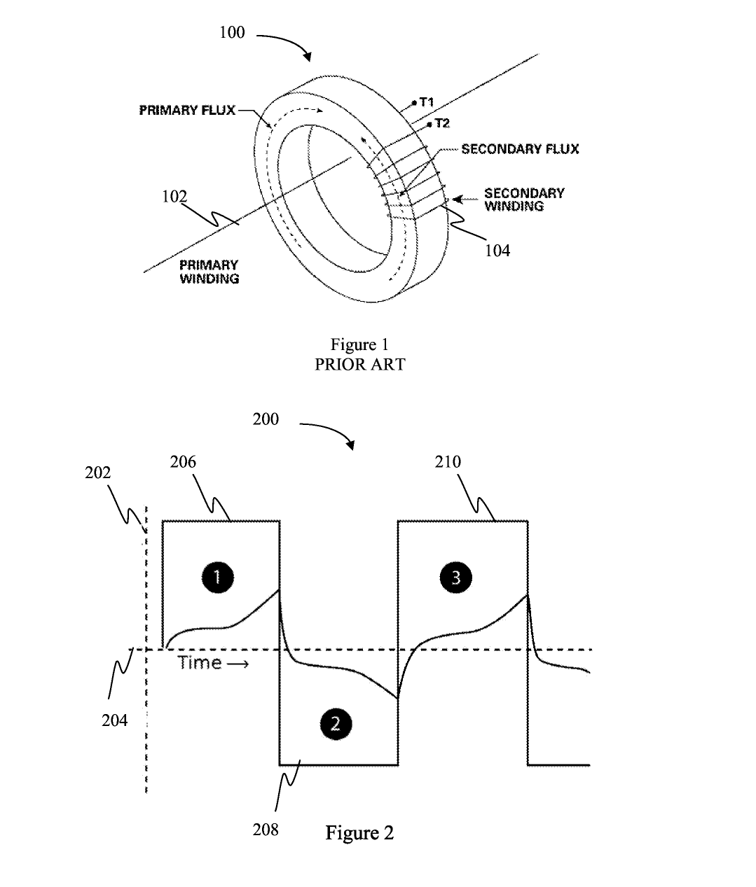

Referring now to FIG. 2, there is shown a graph 200 of applied voltage and current 202 plotted with respect to time 204. As a first voltage 206 is applied to a magnetic assembly the current increases. When a second voltage 208 is applied to the magnetic assembly the current decreases. Finally when a third voltage 210 is applied to the magnetic assembly the current increases.

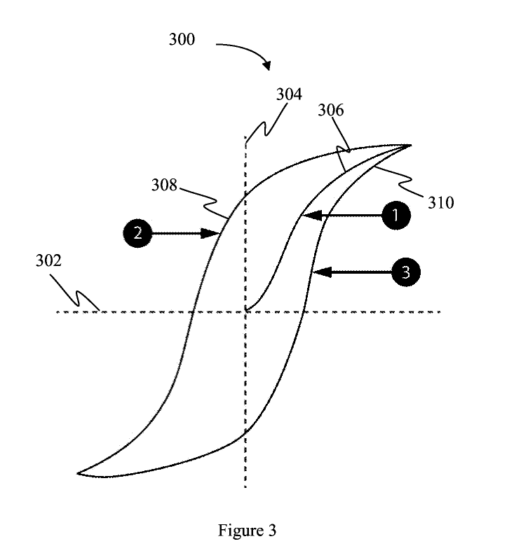

Referring now to FIG. 3, there is shown a graph 300 of integrated DC voltage 304, volt-seconds, plotted with respect to current 302. The plot of the graph 300 corresponds to the voltages applied in graph 200. A first portion 306 of the graph 300 corresponds to the first voltage 206. A second portion 308 of the graph 300 corresponds to the second voltage 208. Finally, a third portion 310 of the graph 300 corresponds to the third voltage 210 applied to the device under test.

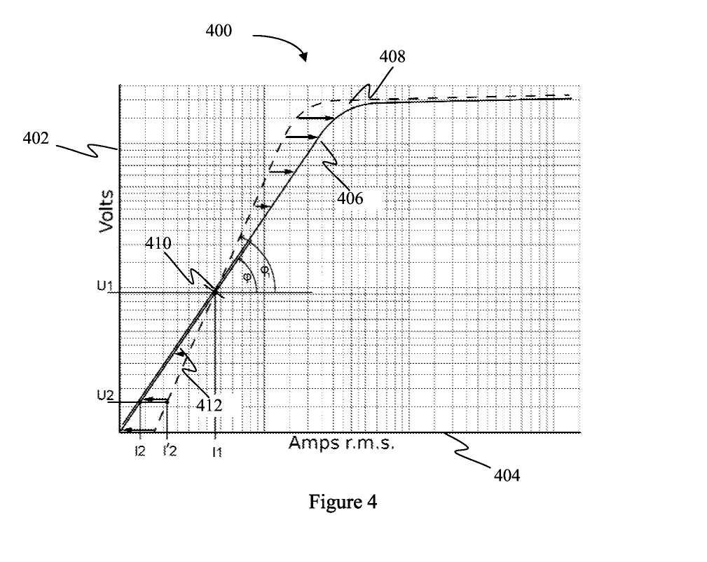

Referring now to FIG. 4, there is shown a graph 400 of the test data run at power frequencies with prior art equipment 406 used as a baseline measurement to determine the curve that the present invention must match. As previously stated, the equipment used to obtain this plot is bulky and high-powered. A short solid line segment 412 is a plot of tests run using the present invention at the same frequencies, but using low voltage and low power. A dashed line 408 is a plot of calculated test data converted to power frequencies, but not yet corrected to match the baseline plot 406.

As can be seen in the graphs 200 and 300, test objects, especially current transformers 100, can be tested by applying a DC test voltage to a winding 104 and measuring voltage, time and current. The volt-seconds from graph 300 are converted to a voltage 402 at the desired power frequency, and the rms value of the current 404, shown in the graph 200, is calculated. This voltage 402 and current 404 represent one single point on the excitation characteristics of the magnetic assembly. A method for calculating these values is now presented. First, a large number of such test points, typically 5 to 10 per decade, each representing a different excitation voltage 402 and current 404 represent the excitation characteristics of the magnetic assembly when tested with at a fixed DC voltage and reversed at different time periods. This characteristic is shown by the dotted line 408 on the graph 400.

Reversing polarity of the DC test voltage 202 can provide a complete full cycle of excitation tests. A calculation of the time integral of the applied voltage for each test point is proportional to the test voltage and is converted to the voltage 402 at the desired power frequency, and the rms value of the current 404 represents the excitation current for that test point. The test points are to be taken over the full range of excitation 408, namely from the fully saturated condition to the fully unsaturated condition. These test points can be shown plotted on log-log graph paper using Eq. 1 to calculate the point's rms current and Eq. 2 to calculate the point's average-reading voltage.

Next, a low level voltage at the desired power frequency is applied to the winding 104 of the magnetic assembly and the excitation current 404 is measured. This test is repeated over a range of voltages 402 so that a graph of this test can be plotted on log-log graph paper 400, where the plot is represented by line 412. As the measurements are gathered and plotted, the two graphs, one plotted using DC excitation 408 and the other using power frequency excitation 412 will cross at a point 410. This point 410 will be at a test condition where the period of the DC time reversal will be approximately equal to the period of the power frequency and the DC voltage and current 408 will be approximately equal to the power frequency voltage and current 412.

To determine the full excitation characteristics of the magnetic assembly at the desired power frequency from a measurement using DC excitation 408, the DC excitation characteristics need to be adjusted. This can be shown graphically, as shown by the arrows in the graph 400. Alternately, this can be done mathematically by a device comprising instructions for determining the adjustment and the equations for the DC excitation 408, the DC excitation characteristics and power frequency excitation 412.

The crossover 410 of the curves is determined and the adjustment in excitation current at any given voltage is calculated. Once the power frequency AC excitation characteristic is known, then other parameters, such as the ANSI/IEEE 45 and ANSI/IEEE 30 degree knee points can be determined.

Each point on the magnetic assembly excitation characteristics is obtained from a single hysteresis plot using DC excitation. The voltage 402 and current 404 for the point is calculated from a large number of measurements. Each measurement comprises a DC voltage, DC current and time. The rms value of the current and the average value of voltage are calculated from the following formulas:

$$\begin{matrix}{I}_{k} = \sqrt{\frac{{\sum }_{i = 1}^{n} {I}_{i}^{2}}{n}} \\ and & ( Eq . 1 ) \\ {U}_{k} = \sqrt{2} \frac{π f}{4} {\sum }_{i = 1}^{n} ( {U}_{i} Δ t ) & ( Eq . 2 )\end{matrix}$$

Where: Iₖ is the rms current at point k, Uₖ—is the voltage at point k, k—number of the point, n—the number of samples for point k, i—number of the sample, Δt—the time interval between samples, f—the power frequency (50 or 60 Hz), Iᵢ and Uᵢ—the readings of DC current and DC voltage at each sample (i=1 to n).

Each of the points has from n=200 to n=800 measurements of current and voltage.

Each point on the excitation curve is the result of calculations based on one hysteresis loop. To accomplish the 20-40 hysteresis loops (20-40 points) 200 to 800 readings of excitation voltage and current are taken on each of the loops.

This raw data 408 must be corrected. The corrected AC readings are determined by applying a correction method to the raw data 408. A correction method is described: First, a sine wave voltage of the power frequency is applied to secondary winding of the magnetic assembly. Then, the resulting excitation current (rms) at several selected voltages is measured. In one embodiment, the selected voltages comprise a range of 1-60 volts. However, as will be appreciated by those with skill in the art with reference to this disclosure, other voltage ranges are possible. The selected voltage range is an exemplar and not intended to be limiting. Next the log-log plot of the AC U/I characteristic curve 412 is examined to determine the angle of the (typically) straight line 412:

$$tan ϕ = \frac{log ( {U}_{1} ) - log ( {U}_{2} )}{log ( {I}_{1} ) - log ( {I}_{2} )} \qquad ( Eq . 3 )$$

Next the log-log plot of the raw data U/I curve 408 is examined in the typically straight-line section of low voltage 402 and current 404 to determine the angle of the curve in this (typically) straight-line area:

$$tan {ϕ}_{1} = \frac{log ( {U}_{t} ) - log ( {U}_{2} )}{log ( {I}_{1} ) - log ( {I}_{2}^{′} )} \qquad ( Eq . 3 A )$$

Finally, a corrected value for current at each measurement point is determined using the formula:

$$log ( {I}_{{i}_{corrected}} ) = log ( {I}_{i} ) + ( log ( {U}_{1} ) - log ( {U}_{i} ) ) ( \frac{1}{tan ( {ϕ}_{1} )} - \frac{1}{tan ( ϕ )} ) \qquad ( Eq . 4 )$$

where Iᵢ is a reading of current (not corrected) at some measurement point, Uᵢ is a corresponding voltage at the same measurement point; φ_{I} is an angle of Volts/Amps of the raw data determined in eq. 3A; φ is the angle of the power-frequency AC characteristic data 412; and U1 and I1 are the point of intersection of the log-log plot of the raw data 408 and the power-frequency plot 412.

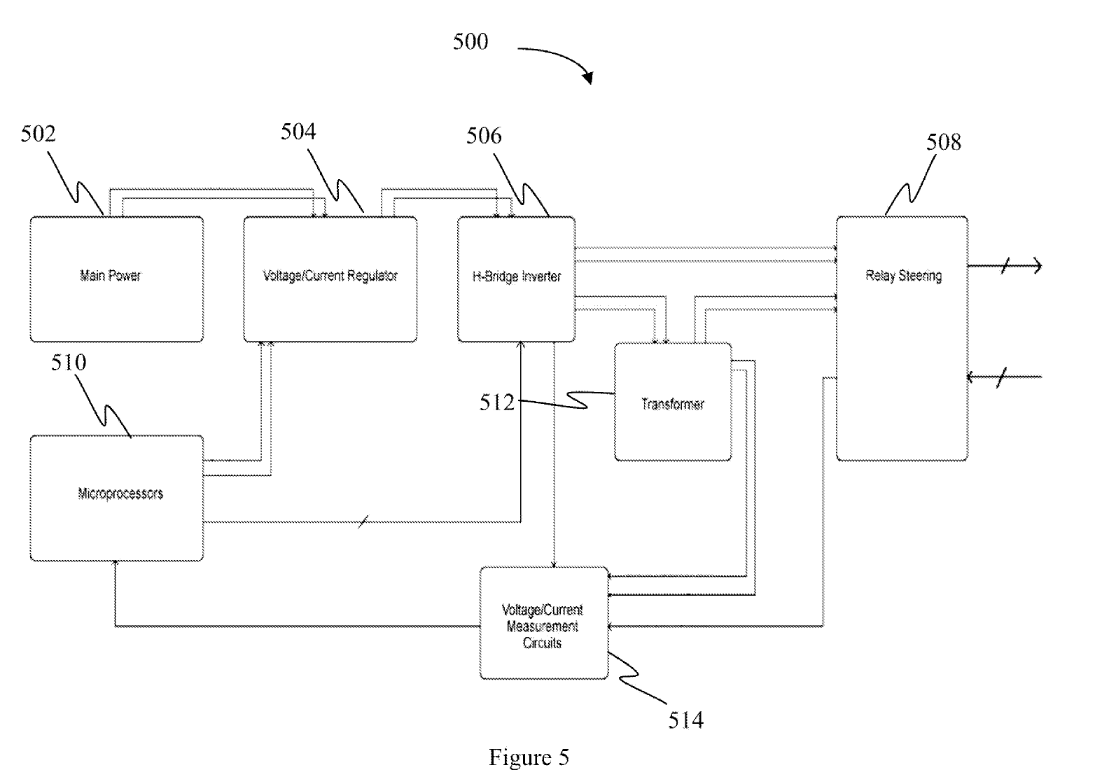

Referring now to FIG. 5, there is shown a device 500 useful to measure the excitation characteristics of a magnetic assembly using reversible direct current. As can be seen the device 500 comprises a main power module 502, a voltage and current regulator 504, an H-bridge inverter 506, a relay steering module 508, one or more than one microprocessors 510, a transformer 512 and one or more than one voltage and current measurement circuits 514.

The device 500 can conduct the DC excitation test on a magnetic assembly, like a magnetic assembly 100 and can be built very light weight so that it can be conveniently carried to a test site instead of the equipment to be tested having to be brought to the test equipment. The power required by the device 500 is very low, so that the device 500 can be powered from any convenient power outlet. The device will now be discussed in detail.

The main power module 502 supplies the required voltage and current necessary to test the magnetic assembly, such as a current transformer 100. Depending upon the application and the equipment to be tested, the device can use batteries, household outlets or higher current and voltage outlets without the need for specialized power to be supplied for the testing device as is prevalent in the current art.

The voltage and current regulator 504 provides accurate and consistent voltages and currents to an H bridge inverter 506. The H bridge inverter 506 comprises an electronic circuit that enables a voltage to be applied across a load in either direction. This provides the necessary reversal of DC voltage to conduct testing of the magnetic assembly. A relay steering circuit 508 receives both DC pulse signals from the H bridge inverter 506 and AC test signals from a transformer 512. The transformer 512 also receives 50 Hz to 240 Hz AC input signals from the H bridge inverter 506 to produce the correct AC test signals. The relay steering circuit 508 can transmit both the DC pulse signals and the AC test signals to the equipment being tested. The relay steering circuit 508 also receives and routes voltages and currents received from the equipment under test and can transmit the received voltages and currents to a voltage and current measurement module 514. The voltage and current measurement module 514 can comprise one or more than one measurement circuits depending upon the application and the equipment that the device 500 is designed to test.

The device 500 and all of the testing is controlled by one or more than one microprocessor 510. The one or more than one microprocessor 510 comprises instructions stored in a memory to control the testing parameters and to receive inputs from the voltage and current measurement module 514 and calculate the adjustment needed to complete tests compliant with the ANSI/IEEE C57.13.1 Standard noted above using the method previously discussed.

What has been described is a new and improved device to measure the excitation characteristics of magnetic assemblies using reversible direct current and a method for converting the direct current (DC) excitation data to alternating current (AC) excitation data at any power frequency, overcoming the limitations and disadvantages inherent in the related art.

Although the present invention has been described with a degree of particularity, it is understood that the present disclosure has been made by way of example and that other versions are possible. As various changes could be made in the above description without departing from the scope of the invention, it is intended that all matter contained in the above description or shown in the accompanying drawings shall be illustrative and not used in a limiting sense. The spirit and scope of the appended claims should not be limited to the description of the preferred versions contained in this disclosure.

All features disclosed in the specification, including the claims, abstracts, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means” for performing a specified function or “step” for performing a specified function should not be interpreted as a “means” or “step” clause as specified in 35 U.S.C. §112.

What is claimed is:

1. A method to measure the excitation characteristics of magnetic assemblies using reversible direct current and converting direct current excitation data to alternating current excitation data at any power frequency, the method comprising the steps of:
a) repeatedly applying a low-level voltage range at power frequencies to a winding of a magnetic assembly;
b) measuring excitation current of the magnetic assembly;
c) determining the magnetic characteristics of the magnetic assembly under test; and
d) calculating one or more than one adjustment values to measure excitation characteristics of the magnetic assembly.

2. The method of claim 1, where the number of repetitions for applying the low-level voltage range at power frequencies is five to ten per decade, where each repetition represents a different excitation voltage and current that represent the excitation characteristics of the magnetic assembly when tested with at a fixed DC voltage and reversed at different time periods.

3. The method of claim 2, where results from the number of repetitions for applying the low-level voltage range at power frequencies are stored in a storage.

4. The method of claim 3, where results are retrieved from the storage and used in the calculation, where the calculation uses an integral of the voltage and the rms current to obtain an approximation of the magnetic characteristics of the magnetic assembly.

5. The method of claim 1, where a portion of the number of repetitions for applying the low-level voltage range at power frequencies are conducted using reverse polarity of the DC test voltage to provide a complete full cycle of excitation tests.

6. The method of claim 5, where the portion is between ten percent and no more than fifty percent.

7. The method of claim 1, where the calculation of the time integral of the applied voltage for each test point is proportional to the test voltage.

8. The method of claim 7, where the time integral of the applied voltage for each test point is converted to the average-reading voltage at the desired power frequency.

9. The method of claim 8, where the rms value of the current represents the excitation current for that test point.

10. The method of claim 7, where the test points are taken over a full range of excitation from a fully saturated condition to a fully unsaturated condition.

11. The method of claim 1, where the calculation uses equations 3, 3A and 4.

12. The method of claim 1, where low level voltage at the desired power frequency is applied to a winding of the magnetic assembly and the excitation current is measured and stored.

13. The method of claim 12, where the test is repeated over a range of voltages and used to calculate the adjustment.

14. The method of claim 13, where the measurements are retrieved and an intersection of the DC excitation and the power frequency excitation is determined.

15. The method of claim 1, further comprising adjusting the DC excitation characteristics to determine the full excitation characteristics of the magnetic assembly at the desired power frequency from a measurement using DC excitation.

16. The method of claim 1, where the calculation further comprises the steps of determining the adjustment and the equations for the DC excitation, the DC excitation characteristics and power frequency excitation.

17. The method of claim 1, further comprising the step of determining other parameters.

18. The method of claim 1, where the voltage and current for each point stored for the calculation is from a large number of measurements.

19. The method of claim 18, where each measurement comprises a DC voltage, a DC current and a time.

20. The method of claim 19, where the rms value of the current is calculated from the formula:
$${I}_{k} = \sqrt{\frac{{\sum }_{i = 1}^{n} {I}_{i}^{2}}{n}}$$

21. The method of claim 19, where an average value of the voltage is calculated from the formula:
$${U}_{k} = \sqrt{2} \frac{π f}{4} {\sum }_{i = 1}^{n} ( {U}_{i} Δ t )$$

22. The method of claim 18, where each point stored for the calculation has between 200 to 800 measurements of current and voltage.

23. The method of claim 1, where the raw data is corrected using the calculated adjustment.

24. The method of claim 23, further comprising a method to determine this correction, the steps of the correction comprising:
a) applying a sine wave voltage of the power frequency to a secondary winding of the magnetic assembly;
b) measuring a resulting excitation current (rms) at several selected voltages;
c) calculating a AC U/I characteristic using the formulas:
$$tan ϕ = \frac{log ( {U}_{1} ) - log ( {U}_{2} )}{log ( {I}_{1} ) - log ( {I}_{2} )}$$
$$and$$
$$tan {ϕ}_{1} = \frac{log ( {U}_{1} ) - log ( {U}_{2} )}{log ( {I}_{1} ) - log ( {I}_{2}^{′} )} ;$$
d) determining a new corrected value for the current using the formula:
$$log ( {I}_{{i}_{corrected}} ) = log ( {I}_{1} ) + ( log ( {U}_{1} ) - log ( {U}_{1} ) ) ( \frac{1}{tan ( {ϕ}_{1} )} - \frac{1}{tan ( ϕ )} )$$
where Iᵢ is a reading of current (not corrected), Uᵢ is a corresponding voltage at the same measurement point; φ1 is an angle of Volts/Amps (not corrected) of the raw data between two low-voltage points U1,I1 and U2,I2′; φ is the angle of the power-frequency low-voltage AC characteristic data between U1,I1 and U2,I2; and U1 and I1 are the point of intersection of the log-log plot of the low voltage raw data and the power-frequency AC characteristic data.

25. The method of claim 24, where the selected voltages comprise a range of 1-60 volts.

26. A device to measure the excitation characteristics of magnetic assemblies using reversible direct current and converting direct current excitation data to alternating current excitation data at any power frequency, the device comprising:
a) a main power module;
b) a voltage and current regulator electrically connected to the main power supply;
c) an H-bridge inverter electrically connected to the voltage and current regulator, a relay steering module and a transformer;
d) a relay steering module electrically connected to magnetic assembly;
e) a transformer electrically connected to one or more than one voltage and current measurement circuits;
f) the one or more than one voltage and current measurement circuits electrically connected to the H-bridge inverter; and
g) one or more than one microprocessors communicatively coupled to the voltage and current regulator, the H-bridge inverter and the one or more than one voltage and current measurement circuits.

27. The device of claim 26, where the main power module supplies the required voltage and current necessary to test a magnetic assembly,

28. The device of claim 26, where main power module can comprise batteries, 110V or 220V.

29. The device of claim 26, where the voltage and current regulator provides accurate and consistent voltages and currents to the H bridge inverter.

30. The device of claim 26, where the H bridge inverter comprises an electronic circuit that enables a voltage to be applied across a load in either direction, where the H bridge inverter provides the necessary reversal of DC voltage to conduct testing of the magnetic assembly. A relay steering circuit receives both DC pulse signals from the H bridge inverter and AC test signals from a transformer.

31. The device of claim 26, where the transformer receives input signals from the H bridge inverter to produce the correct AC test signals, where the input signals are from 50 Hz to 240 Hz AC.

32. The device of claim 26, where the relay steering circuit can transmit both the DC pulse signals and the AC test signals to the magnetic assembly being tested.

33. The device of claim 26, where the relay steering circuit receives and routes voltages and currents received from the magnetic assembly under test and can transmit the received voltages and currents to a voltage and current measurement module.

34. The device of claim 26, where the voltage and current measurement module comprises one or more than one measurement circuits.

35. The device of claim 26, where the one or more than one microprocessor controls all operation of the device and all of the testing for the magnetic assembly.

36. The device of claim 35, where the one or more than one microprocessor comprise instructions stored in a memory to control the testing parameters, receive inputs from the voltage and current measurement module and calculate an adjustment needed to complete tests compliant with the ANSI/IEEE C57.13.1 Standard.
